(19) United States
(12) Patent Application Publication
(10) Pub. No.: US 2011/0279162 A1
(43) Pub. Date: Nov. 17, 2011

(54) Signal conditioning system with a sigma-delta modulator

(75) Inventors: Jijian Deng, Chengdu (CN); Xiu Yang, Chengdu (CN)

(73) Assignee: IPGoal Microelectronics (SiChuan) Co., Ltd.

(21) Appl. No.: 13/105,870

(22) Filed: May 11, 2011

(30) Foreign Application Priority Data
May 12, 2010 (CN) 201010170382.4

(51) Int. Cl. H03K 5/00

(52) U.S. Cl. 327/311

(57) ABSTRACT

A signal conditioning system includes a first filter, a signal processing module connected with the first filter, a second filter connected with the signal processing module, and a Σ-Δ modulator connected with the second filter. The signal processing module makes the saturation overflow treatment to the signal output by the first filter using the characteristics of the radix complement adder. The Σ-Δ modulator is a high order filter formed by a plurality of cascaded and inter-stage feedback second-order filters. Based on the performance of the Σ-Δ modulator and the whole system, the stability of the signal conditioning system is improved.

### BACKGROUND OF THE PRESENT INVENTION

1. Field of Invention

The present invention relates to a signal conditioning system, and more particularly to a stable signal conditioning system with the high-performance Σ-Δ modulator.

2. Description of Related Arts

There are two types of digital filters: the IIR filter and the FIR filter. The IIR filter has, in general, some advantages of higher performance at the lower level, rapid execution speed and fewer storage units, thereby attracting the attention of large numbers of IC designers. In the digital signal processing, the quantitative processing is non-linear, so that the digital filter turns to be a non-linear system. Owing to the feedback loop existing in the IIR filter, the self-oscillation is generated under certain conditions, which leads to the overflow of the filter. Furthermore, while seriously overflowing, the poles within the unit circle are deviated outside the unit circle, which leads to the crash of the whole system.

Since 1962, in which the first Σ-Δ modulator architecture was put forward, the Σ-Δ modulator has been developed for decades. The researches on the stability of the Σ-Δ modulator are countless. However, the completely accurate estimation to the stability of the Σ-Δ modulator still has not been exactly described.

The conventional two solutions are described as follows. The first method is to add the word length and reduce the limit cycle oscillation. Add the bit width of the quantitative data and improve the quantitative accuracy of the filter such that the coefficients of the filter approximate the ideal situation. Accordingly, the zero pole of the filter is located within the unit circle, thereby improving the stability of the system. The method of adding the word length can well approximate the ideal performance of the filter. However, owing to add the bit width, the difficulty of quantization is increased, and simultaneously the data processing of the system is increased. The second method is to adjust the input sampling data. Deal with the input signals and reduce the amplitude of the input data. However, if the input signals are adjusted to be lower, the level of the output signal of the filter will be reduced. Therefore, an operational amplifier is mostly needed in the last part of the hardware design to amplify the output signal, which obviously increases the structure of the system.

### SUMMARY OF THE PRESENT INVENTION

An object of the present invention is to provide a signal conditioning system with a Σ-Δ modulator, which is capable of significantly improving the stability of the system.

Accordingly, in order to accomplish the above object, the present invention provides a signal conditioning system, comprising a first filter, a signal processing module connected with the first filter, a second filter connected with the signal processing module, and a Σ-Δ modulator connected with the second filter, wherein the signal processing module makes a saturation overflow treatment to a signal output by the first filter using characteristics of a radix complement adder, the Σ-Δ modulator is a high order filter formed by a plurality of cascaded and inter-stage feedback second-order filters.

Compared with the prior art, according to the changes of different signals in the signal conditioning system, the present invention controls the abnormal signals by the subsystem before the Σ-Δ modulator without affecting the normal signals, such that the abnormal signals meet the normal operating range of the filter before being input to the Σ-Δ modulator. Simultaneously, the structure of the Σ-Δ modulator is optimized, the high order filter integrating the multi-level cascade with the inter-stage feedback is achieved, and the stability of the filter itself is improved. By the combination of the above two schemes, based on ensuring the performance of the Σ-Δ modulator and the whole system, the stability of the signal conditioning system is significantly improved.

These and other objectives, features, and advantages of the present invention will become apparent from the following detailed description, the accompanying drawings, and the appended claims.

### BRIEF DESCRIPTION OF THE DRAWINGS

FIG. 1 is a system architecture diagram of a signal conditioning system with the Σ-Δ modulator according to a preferred embodiment of the present invention.

FIG. 2 is a schematic diagram of the signal processing module shown in FIG. 1.

FIG. 3 is the structural diagram of the Σ-Δ modulator shown in FIG. 1.

### DETAILED DESCRIPTION OF THE PREFERRED EMBODIMENT

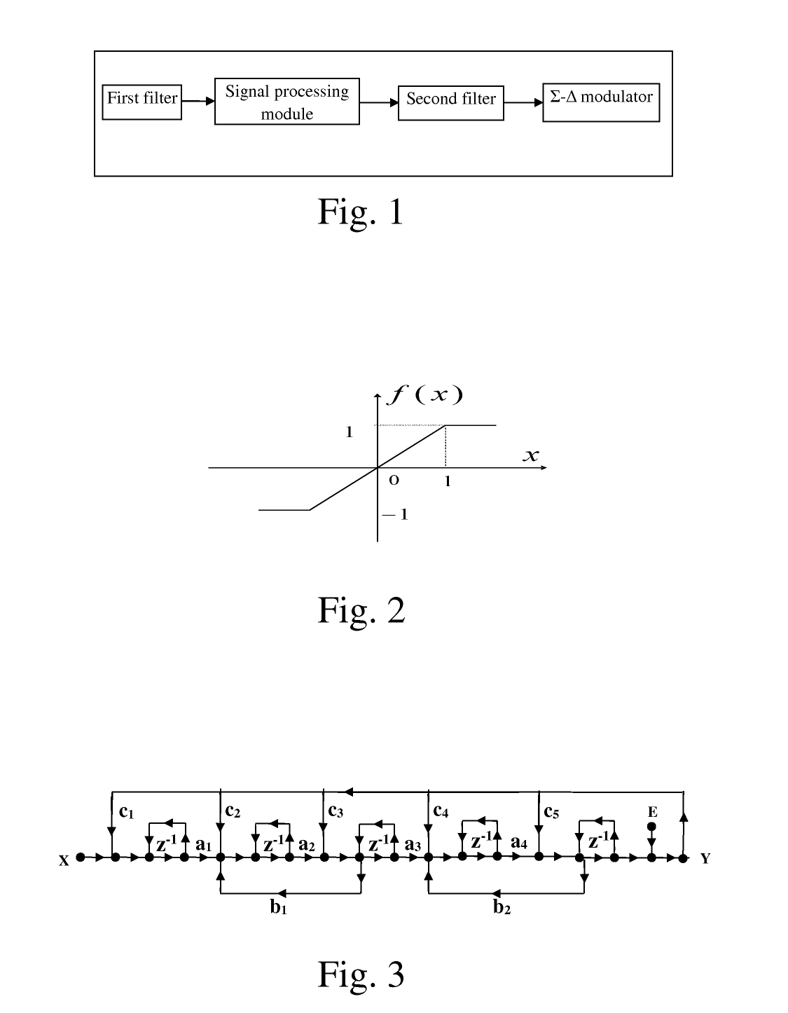

Referring to FIG. 1 of the drawings, a signal conditioning system with the Σ-Δ modulator according to a preferred embodiment of the present invention is illustrated, wherein the signal conditioning system comprises a first filter, a signal processing module connected with the first filter, a second filter connecting with the signal processing module, and a Σ-Δ modulator connecting with the second filter.

By changing the structure of the Σ-Δ modulator, the signal conditioning system of the present invention transforms the high-order filter into the multi-order cascaded filter and introduces the negative feedback among the levels, thereby improving the performance of the system. Simultaneously, based on ensuring the performance of the Σ-Δ modulator and the signal conditioning system, the data between the filters are adjusted by the signal processing module to effectively solve the overflow problem, thereby significantly improving the stability of the signal conditioning system.

As shown in FIG. 1, in order not to affect the normal signal transmission, the signal processing module for processing the signal is added between the first filter and the second filter. FIG. 2 is the schematic diagram of the signal processing module illustrating the operational principle thereof. The signal processing module makes the overflow treatment to the signal using the input and output characteristic of the radix complement adder shown in FIG. 2. When the input is |x|, the addition result is limited between the maximum value and the minimum value. If the overflow is detected, the total is set to be the maximum allowable value.

An input signal is filtered by the first filter, and then the filtered signal is input to the signal processing module. The signal processing module uses the complement algorithm of the saturated overflow treatment, in such a manner that the amplitude of the signal is limited based on the normal range of the data signal, so that the spike pulse and glitch of the signal with high power is truncated, thus ensuring the stability of the back-end signal. The signal output by the signal processing module is filtered by the second filter so that the high-frequency component generated by the signal truncation is eliminated, and then the signal is input to the Σ-Δ modulator.

The unit impulse response of the IIR filter has the infinite time width, and the transfer function thereof has poles on the limited Z plane, and simultaneously the IIR filter has the feedback from the output to the input. Therefore, the IIR filter has the recursive structure and can be achieved by various network structures. However, different network structures will bring to different operating errors, and have different stabilities, operation speeds and storage spaces.

Referring to FIG. 3, the Σ-Δ modulator is a high order IIR filter formed by a plurality of cascaded second-order IIR filters, wherein every second-order IIR filter adopts the direct form II. The number of the delay units depends on the poles of the current level second-order IIR filter and the zeroes of the next level second-order IIR filter. By mixing the poles of the previous level IIR filter with the zeroes of the next level IIR filter, the number of the delay units is reduced, the instructions are accordingly reduced, and the processing speed is quickened. Furthermore, two feedback loops are introduced to lower the sensitivity of the pole to every coefficient deviation, thereby improving the stability of the system.

In the preferred embodiment of the present invention, the Σ-Δ modulator is a 5^{th}-order Σ-Δ modulator which comprises a signal input end x for receiving the output signal of the second filter, a signal output end y, a signal adjustment end E for adjusting the output signal and five integrators Z₋₁ connected with each other. a1, a2, a3 and a4 are the gain coefficients of every two orders, b1 is the feedback coefficient of the 3^{rd}-order and the 2^{nd}-order, b2 is the feedback coefficient of the 5^{th}-order and the 4^{th}-order, c1, c2, c3, c4 and c5 are the feedback coefficients of every two orders.

By the audio analyzer, the 1K sinusoidal signal is input to test the performance indexes of the Σ-Δ modulator. The test result is SNR (signal to noise ratio)=90 db (decibel), and THD (total harmonic distortion)=81. It can be seen that the Σ-Δ modulator of the preferred embodiment of the present invention effectively improves the performance of the signal conditioning system.

According to the change of different signals in the signal conditioning system, the present invention controls the abnormal signals by the subsystem before the Σ-Δ modulator without affecting the normal signals, such that the abnormal signals meet the normal operating range of the IIR filter before being input to the Σ-Δ modulator. Simultaneously, the structure of the Σ-Δ modulator is optimized, the high order IIR filter integrating the multi-level cascade with the inter-stage feedback is achieved, and the stability of the IIR filter itself is improved. By the combination of the above two schemes, based on ensuring the performance of the Σ-Δ modulator and the whole system, the stability of the signal conditioning system is significantly improved.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A signal conditioning system, comprising a first filter, a signal processing module connected with said first filter, a second filter connected with said signal processing module; and a Σ-Δ modulator connected with said second filter, wherein said signal processing module makes a saturation overflow treatment to signals output by said first filter using characteristics of a radix complement adder, said Σ-Δ modulator is a high order filter formed by a plurality of cascaded and inter-stage feedback second-order filters.

2. The signal conditioning system, as recited in claim 1, wherein said signal processing module limits amplitudes of said signals output by said first filter and truncates spike pulses and glitches of signals with high power, thereby ensuring a stability of a back-end signal.

3. The signal conditioning system, as recited in claim 2, wherein said second filter filters signals output by said signal processing module for eliminating high-frequency components generated by signal truncation, and then said filtered signals are sent to said Σ-Δ modulator.

4. The signal conditioning system, as recited in claim 1, wherein said Σ-Δ modulator is a 5^{th}-order Σ-Δ modulator comprising a signal input end for receiving signals output by said second filter, five integrators connected with each other, a signal adjustment end for adjusting output signals and a signal output end connecting with said signal adjustment end.

5. The signal conditioning system, as recited in claim 4, wherein a gain coefficient is provided between every two orders.

6. The signal conditioning system, as recited in claim 4, wherein a negative feedback is introduced between every two orders, a negative coefficient is provided between every two orders.

7. The signal conditioning system, as recited in claim 5, wherein a negative feedback is introduced between every two orders, a negative coefficient is provided between every two orders.

8. The signal conditioning system, as recited in claim 4, wherein a first feedback loop is provided between a 3^{rd}-order and a 2^{nd}-order of said Σ-Δ modulator, a second feedback loop is provided between a 5^{th}-order and 4^{th}-order of said Σ-Δ modulator, said to first and second feedback loops respectively have two feedback coefficients.

9. The signal conditioning system, as recited in claim 5, wherein a first feedback loop is provided between a 3^{rd}-order and a 2^{nd}-order of said Σ-Δ modulator, a second feedback loop is provided between a 5^{th}-order and 4^{th}-order of said Σ-Δ modulator, said first and second feedback loops respectively have two feedback coefficients.

10. The signal conditioning system, as recited in claim 6, wherein a first feedback loop is provided between a 3^{rd}-order and a 2^{nd}-order of said Σ-Δ modulator, a second feedback loop is provided between a 5^{th}-order and 4^{th}-order of said Σ-Δ modulator, said first and second feedback loops respectively have two feedback coefficients.

11. The signal conditioning system, as recited in claim 7, wherein a first feedback loop is provided between a 3^{rd}-order and a 2^{nd}-order of said Σ-Δ modulator, a second feedback loop is provided between a 5^{th}-order and 4^{th}-order of said Σ-Δ modulator, said first and second feedback loops respectively have two feedback coefficients.
